(19) United States
(12) Patent Application Publication
(10) Pub. No.: US 2025/0212586 A1
(43) Pub. Date: Jun. 26, 2025

(54) LIGHT-EMITTING ELEMENT, LIGHT-EMITTING DEVICE AND DISPLAY DEVICE

(71) Applicant: HUBEI SAN'AN OPTOELECTRONICS CO., LTD., Ezhou (CN)

(72) Inventors: Yao Yan, Ezhou (CN); Jin XU, Ezhou (CN); BAOJUN SHI, Ezhou (CN); Shuijie WANG, Ezhou (CN); Fei Liu, Ezhou (CN)

(21) Appl. No.: 19/001,561

(22) Filed: Dec. 26, 2024

(30) Foreign Application Priority Data
Dec. 26, 2023 (CN) 2023118300813

(51) Int. Cl. H10H 29/80; H01L 25/075; H10H 20/812; H10H 20/825

(52) U.S. Cl. CPC H10H 29/8421; H01L 25/0753; H10H 20/812; H10H 20/825; H10H 29/942

(57) ABSTRACT

A light-emitting element, a light-emitting device and a display device are provided, which relate to the technical filed of semiconductor devices. The light-emitting element is a flip-chip light-emitting diode, and has a light-emitting surface and a backlight surface respectively located on outermost sides of the flip-chip light-emitting diode and opposite to each other; the flip-chip light-emitting diode includes an epitaxial staked layer configured to generate predetermined light; and a light-splitting layer disposed on a side of the epitaxial stacked layer proximate to the light-emitting surface; the light-splitting layer is configured to reflect predetermined light with an incident complementary angle of a first angle, transmit predetermined light with an incident complementary angle of a second angle, and reflect predetermined light with an incident complementary angle of a third angle; and the first angle is smaller than the second angle, and the second angle is smaller than the third angle.

### CROSS-REFERENCE TO RELATED APPLICATION

This application claims priority to Chinese Patent Application No. 202311830081.3, filed on Dec. 26, 2023, which is herein incorporated by reference in its entirety.

### TECHNICAL FIELD

The disclosure relates to the technical field of semiconductor devices, and more particularly to a light-emitting element, a light-emitting device and a display device.

### BACKGROUND

In order to improve light-emitting uniformity of a display panel, a demand for large-angle light-emitting elements is increasing. With the rise of mini backlight applications, the large-angle light-emitting elements, especially large-angle mini light-emitting diodes (LEDs), are becoming more and more popular in the market.

Compared to traditional LED chips, the large-angle mini-LEDs are arranged more sparsely in the backlight application end, and do not require additional lenses for secondary light distribution, which greatly reduces costs. However, control of a light-emitting angle of a mini semiconductor light-emitting element is a key and difficult point in its technical route. In order to ensure large-angle light emission of the chips, most of the current large-angle LED chips use reflective layers such as metal vapor deposition and a distributed Bragg reflector (DBR) on the light-emitting surface of the chip to control the light to be emitted from a side of the chip to achieve a purpose of large-angle light emission. However, the light will be absorbed by an epitaxial layer and metal during a process of reflecting back and forth in the chip, which greatly reduces the light-emitting efficiency of the chip.

Therefore, how to improve the light-emitting angle of the light-emitting element while achieving excellent light-emitting efficiency is a technical problem that those skilled in the art need to solve urgently.

### SUMMARY

In view of this, in order to solve the above technical problems, the disclosure provides the following technical solutions.

In order to achieve the above purpose, a technical solution adopted by the disclosure is to provide a light-emitting element, the light-emitting element is a flip-chip light-emitting diode, and has a light-emitting surface and a backlight surface respectively located on outermost sides of the flip-chip light-emitting diode and opposite to each other. The flip-chip light-emitting diode includes an epitaxial staked layer and a light-splitting layer, and the epitaxial stacked layer is configured to generate predetermined light. The light-splitting layer is disposed on a side of the epitaxial stacked layer proximate to the light-emitting surface.

The light-splitting layer is configured to reflect predetermined light with an incident complementary angle of a first angle, transmit predetermined light with an incident complementary angle of a second angle, and reflect predetermined light with an incident complementary angle of a third angle. The first angle is smaller than the second angle, and the second angle is smaller than the third angle.

In order to solve the above technical problems, a technical solution adopted by the disclosure is to provide a light-emitting element, and the light-emitting element has a light-emitting surface and a backlight surface respectively located on outermost sides of the light-emitting element and opposite to each other. The light-emitting element includes a light-emitting functional layer, a light-splitting layer and an insulating reflective layer. The light-emitting functional layer is configured to generate predetermined light. The light-splitting layer is disposed on a side of the light-emitting functional layer proximate to the light-emitting surface. The insulating reflective layer is disposed on a side of the light-emitting functional layer proximate to the backlight surface.

The insulating reflective layer is configured to reflect incident predetermined light. The light-splitting layer is configured to reflect predetermined light with an incident complementary angle of a first angle, transmit predetermined light with an incident complementary angle of a second angle, and reflect predetermined light with an incident complementary angle of a third angle. The first angle is smaller than the second angle, and the second angle is smaller than the third angle.

In order to solve the above technical problems, a technical solution adopted by the disclosure is to provide a light-emitting device, the light-emitting device includes an encapsulation bracket and the light-emitting element, and the light-emitting element is fixed on the encapsulation bracket, and is the aforementioned light-emitting element.

In order to solve the above technical problems, a technical solution adopted by the disclosure is to provide a display device, the display device includes multiple light-emitting elements, and each of the multiple light-emitting elements is the aforementioned light-emitting element.

The beneficial effects are as follows. It is different from the related art, in the disclosure, the light-splitting layer reflects the predetermined light with the incident complementary angles of the first angle and the third angle, thereby reducing the amount of light leakage from the backlight surface, and improving the amount of light emission from a side surface of the light-emitting element, to improve a light-emitting angle of the light-emitting element. The light-splitting layer transmits the predetermined light with the incident complementary angle of the second angle, so that the light incident on the light-splitting layer with the incident complementary angle of the third angle can transmit the light-splitting layer and be emitted from the light-emitting surface, thereby reducing the amount of light absorbed inside the light-emitting element, and further enabling the light-emitting element have excellent light-emitting efficiency. Therefore, the disclosure can improve the light-emitting angle of the light-emitting element while achieving the excellent light-emitting efficiency.

### BRIEF DESCRIPTION OF DRAWINGS

FIG. 1 illustrates a schematic structural diagram of a traditional flip-chip.

FIG. 2 illustrates a schematic structural diagram of another traditional flip-chip according to an embodiment of the disclosure.

FIG. 3 illustrates a schematic structural diagram of a light-emitting element of the disclosure.

FIG. 4 illustrates a schematic structural diagram of a light-splitting layer of the light-emitting element of the disclosure.

FIG. 5 illustrates a schematic diagram of reflective situations of the light-splitting layer of the light-emitting element for predetermined light with different incident complementary angles according to an embodiment of the disclosure.

FIG. 6 illustrates a schematic diagram of a relationship comparison between reflectivities and incident complementary angles in a light-splitting layer of a first light-emitting element in an experiment group 1 and in a light-splitting layer of a second light-emitting element in a control group 1.

FIG. 7 illustrates a schematic diagram of a relationship comparison between a reflectivity and an incident complementary angle in a light-splitting layer with an idea state of the first light-emitting element in the experiment group 1.

FIG. 8 illustrates a schematic diagram of a relationship between an optical thickness and a layer serial number of each material layer in the light-splitting layer of the first light-emitting element in the experiment group 1.

FIG. 9 illustrates a schematic diagram of a relationship between an optical thickness and a layer serial number of each material layer in the light-splitting layer of the second light-emitting element in the control group 1.

FIG. 10 illustrates a schematic diagram of a first light pattern according to an embodiment of the disclosure.

FIG. 11 illustrates a schematic diagram of a second light pattern according to an embodiment of the disclosure.

FIG. 12 illustrates a schematic diagram of a third light pattern according to an embodiment of the disclosure.

FIG. 13 illustrates a schematic diagram of a fourth light pattern according to an embodiment of the disclosure.

### DESCRIPTION OF REFERENCE SIGNS

100—flip-chip LED chip; 101—light-emitting surface; 102—backlight surface; 110—epitaxial stacked layer; 120—insulating reflective layer; 130—substrate; 140—DBR reflective layer;
200—light-emitting element; 200a—flip-chip light-emitting diode; 201—light-emitting surface; 202—backlight surface; 210—light-emitting functional layer; 210a—epitaxial stacked layer; 220—light-splitting layer; 230—insulating reflective layer; 240—substrate; 250—first contact electrode; 260—second contact electrode; 270—first pad electrode; 280—second pad electrode; and
α—first angle; θ—second angle; β—third angle; 211a—first semiconductor layer; 212a—light-emitting layer; 213a—second semiconductor layer; 221—dielectric unit; 222—first material layer; 223—second material layer.

### DETAILED DESCRIPTION OF EMBODIMENTS

In order to enable those skilled in the art to better understand the technical solution of the disclosure, the disclosure is further described in detail below in conjunction with the accompanying drawings and embodiments. Apparently, the described embodiments are merely some of the embodiments of the disclosure, rather than all of them. Based on the embodiments in the disclosure, all other embodiments obtained by those skilled in the art without creative work are within a scope of protection of the disclosure.

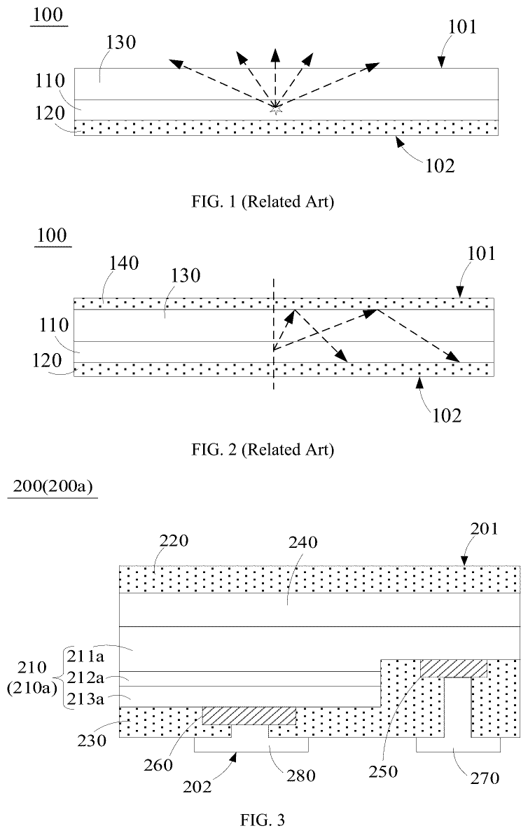

Referring to FIG. 1, a traditional light-emitting element such as a flip-chip LED chip 100 has a light-emitting surface 101 and a backlight surface 102 respectively located on outermost sides of the flip-chip LED chip 100 and opposite to each other. It should be understood that no matter how a structure of the flip-chip LED chip 100 changes, the light-emitting surface 101 and the backlight surface 102 both refer to the outermost surfaces of the flip-chip LED chip 100. An insulating reflective layer 120 is disposed on a side of an epitaxial stacked layer 110 proximate to the backlight surface 102, so that light emitted by the epitaxial stacked layer 110 is emitted from a side of a substrate 130 facing towards the light-emitting surface 101. Dashed lines each with an arrow in FIG. 1 represent the light emitted by the epitaxial stacked layer 110, as shown in FIG. 1, a light-emitting angle of the flip-chip LED chip 100 is small, which cannot achieve a good light-emitting effect.

In order to ensure large-angle light emission of the chip, as shown in FIG. 2, the flip-chip LED chip 100 further includes a DBR reflective layer 140 disposed on a side of the substrate 130 proximate to the light-emitting surface 101. An incident complementary angle is a complementary angle of an incident angle, and the DBR reflective layer 140 can reflect a part of the light emitted by the epitaxial stacked layer 110 and incident at each incident complementary angle. Dashed lines each with an arrow in FIG. 2 represent the light emitted by the epitaxial stacked layer 110, as shown in FIG. 2, the light incident on the DBR reflective layer 140 at each incident complementary angle is reflected by the DBR reflective layer 140 regardless the value of the incident complementary angle. Such that the light emitted by the epitaxial stacked layer 110 and incident on the DBR reflective layer 140 at each incident complementary angle is further reflected back and forth between the DBR reflective layer 140 and the insulating reflective layer 120 after being reflected by the DBR reflective layer 140, in this process, the light reflected back and forth will be largely absorbed by the epitaxial stacked layer 110 and a metal layer (not shown in drawings) in the flip-chip LED chip 100, resulting in reducing light-emitting efficiency of the flip-chip LED chip 100.

Therefore, how to improve the light-emitting angle of the light-emitting element while achieving excellent light-emitting efficiency is a technical problem that those skilled in the art need to solve urgently.

In order to solve the above problems, inventors of the disclosure have proposed the following embodiments after research.

As shown in FIGS. 3-5, a light-emitting element 200 of the disclosure has a light-emitting surface 201 and a backlight surface 202 respectively located on outermost sides of the light-emitting element 200 and opposite to each other. It should be understood that no matter how a structure of the light-emitting element 200 changes, the light-emitting surface 201 and the backlight surface 202 both refer to the outermost surfaces of the light-emitting element 200. The light-emitting element 200 includes a light-emitting functional layer 210, a light-splitting layer 220 and an insulating reflective layer 230. The light-emitting functional layer 210 is configured to generate predetermined light. The light-splitting layer 220 is disposed on a side of the light-emitting functional layer 210 proximate to the light-emitting surface 201. The insulating reflective layer 230 is disposed on a side of the light-emitting functional layer 210 proximate to the backlight surface 202.

Dashed lines each with an arrow in FIG. 5 represent predetermined light, as shown in FIG. 5, the insulating reflective layer 230 is configured to reflect incident predetermined light. The incident complementary angle is a complementary angle of an incident angle, that is, a horizontal angle between the predetermined light and the light-splitting layer 220. Thus, the light-splitting layer 220 is configured to reflect predetermined light with an incident complementary angle of a first angle α, transmit predetermined light with an incident complementary angle of a second angle θ, and reflect predetermined light with an incident complementary angle of a third angle β. The first angle α is smaller than the second angle θ, and the second angle θ is smaller than the third angle β.

By the above methods, in the disclosure, the light-splitting layer 220 reflects the predetermined light with the incident complementary angles of the first angle α and the third angle β, thereby reducing the amount of light leakage from the backlight surface 202, and improving the amount of light emission from a side surface of the light-emitting element 200, to improve a light-emitting angle of the light-emitting element 200. The light-splitting layer 220 transmits the predetermined light with the incident complementary angle of the second angle θ, so that effects on at least two aspects are obtained. On the one hand, the light incident on the light-splitting layer 220 and with the incident complementary angle of the second angle θ can transmit the light-splitting layer 220 to be emitted from the light-emitting surface 201, thereby reducing the amount of the light absorbed inside the light-emitting element 200, and further enabling the light-emitting element 200 have excellent light-emitting efficiency. On the other hand, since the first angle α is smaller than the second angle θ, and the second angle θ is smaller than the third angle, after the light with the incident complementary angles of the first angle α is reflected by the light-splitting layer 220, a number of back and forth reflections between the light-splitting layer 220 and the insulating reflective layer 230 of the light with the incident complementary angles of the first angle α is less than that of the light with the incident complementary angle of the second angle θ and the light with the incident complementary angle of the third angle β, thereby reducing the amount of the light absorbed inside the light-emitting element 200.

It should be understood that the light-emitting functional layer 210 in the disclosure refers to a structure that can provide a light source and is distributed in layers.

In an embodiment, referring to FIG. 3, the light-emitting element 220 can be a flip-chip light-emitting diode 200a, and the light-emitting functional layer 210 is an epitaxial stacked layer 210a. The epitaxial stacked layer 210a includes a first semiconductor layer 211a, a light-emitting layer 212a and a second semiconductor layer 213a stacked in that order.

In an embodiment, referring to FIG. 3, the flip-chip light-emitting diode 200a includes a substrate 240, the epitaxial stacked layer 210a is disposed on a side of the substrate 240 facing towards the backlight surface 202, and the light-splitting layer 220 is disposed on a side of the substrate 240 facing towards the light-emitting surface 201.

Specifically, the light-emitting layer 212a is configured to emit predetermined light, and the light-emitting layer 212a can include a multiple quantum well (MQW) structure with repeatedly and alternately stacked quantum well layers and quantum barrier layers. For example, the quantum well layers and the quantum barrier layers can be InₓAl_{y}Ga_{1-x-y}N (where 0≤x≤1, 0≤y≤1 and 0≤x+y≤1) with different components. For example, the quantum well layers may be InₓGa₁₋ₓN, where 0<x≤1, and the quantum barrier layers may be gallium nitride (GaN) or aluminum gallium nitride (AlGaN). The light-emitting layer 212a is not limited to the MQW structure, and may further have a single quantum well (SQW) structure. The first semiconductor layer 211a may be a nitride semiconductor layer including n-type InₓAl_{y}Ga_{1-x-y}N (where 0≤x<1, 0≤y<1 and 0≤x+y<1), and n-type impurity may be silicon (Si). For example, the first semiconductor layer 211a may include n-type GaN. The second semiconductor layer 213a may be a nitride semiconductor layer including p-type InₓAl_{y}Ga_{1-x-y}N (where 0≤x<1, 0≤y<1 and 0≤x+y<1), and p-type impurity may be magnesium (Mg). For example, according to the exemplary embodiments, the second semiconductor layer 213a can have a single structure, or have a multilayer structure including layers with different components.

In an embodiment, referring to FIG. 3, the flip-chip light-emitting diode 200a includes a first contact electrode 250, a second contact electrode 260, a first pad electrode 270 and a second pad electrode 280. The first contact electrode 250 and the second contact electrode 260 are isolated from each other, and are disposed on a side of the epitaxial stacked layer 210a facing towards the backlight surface 202. The first contact electrode 250 is electrically connected to the first semiconductor layer 211a, and the second contact electrode 260 is electrically connected to the second semiconductor layer 213a. The first pad electrode 270 and the second pad electrode 280 are disposed on a side of the insulating reflective layer 230 facing towards the backlight surface 202, the first pad electrode 270 is electrically connected to the first contact electrode 250, and the second pad electrode 280 is electrically connected to the second contact electrode 260.

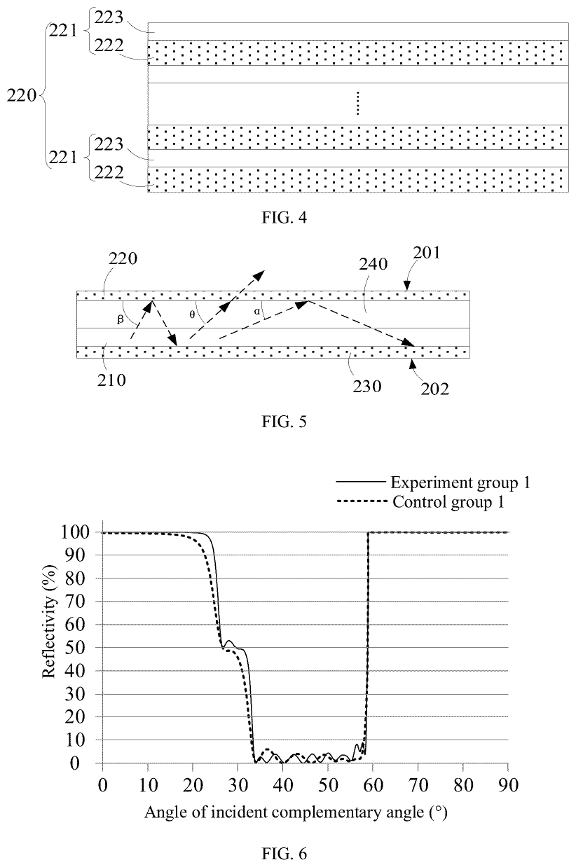

In an embodiment, referring to FIG. 4 in combination with FIG. 3, the light-splitting layer 220 includes multiple layers of dielectric units 221, and the multiple layers of dielectric units 221 cooperate with each other to achieve functions of the light-splitting layer 220. Each dielectric unit 221 includes a first material layer 222 and a second material layer 223. In each dielectric unit 221, the first material layer 222 is located on a side of the second material layer 223 proximate to the epitaxial stacked layer 210a, an optical thickness of the first material layer 222 is greater than that of the second material layer 223, and a refractive index of the first material layer 222 is lower than that of the second material layer 223.

Through the above methods, the reflective effect of each dielectric unit 221 can be configured reasonably, so that the dielectric units 221 cooperate with each other to achieve the functions of the light-splitting layer 220.

In an embodiment, the first material layer 222 includes, but is not limited to a silica (SiO₂) layer, and the second material layer 223 includes, but is not limited to a titanium oxide (Ti₃O₅) layer. In another embodiment, the first material layer 222 includes, but is not limited to a silica (SiO₂) layer, and the second material layer 223 includes, but is not limited to a niobium oxide (Nb₂O₃) layer. Still in another embodiment, the first material layer 222 includes, but is not limited to an aluminum arsenide (AlAs) layer, and the second material layer 223 includes, but is not limited to a gallium arsenide (GaAs) layer.

In an embodiment, as shown in FIG. 5, a reflectivity of the light-splitting layer 220 on predetermined light with the incident complementary angle of the first angle α and a wavelength of 420 nanometers (nm) to 470 nm (for example, including the wavelength of 420 nm, 445 nm and 470 nm) is at least 95%. A transmissivity of the light-splitting layer 220 on predetermined light with the incident complementary angle of the second angle θ and a wavelength of 380 nm to 440 nm (for example, including the wavelength of 380 nm, 414 nm and 444 nm) is at least 90%. A reflectivity of the light-splitting layer 220 on predetermined light with the incident complementary angle of the third angle β and a wavelength of 380 nm to 410 nm (for example, including the wavelength of 380 nm, 395 nm and 410 nm) is at least 98%.

In an embodiment, the first angle α is in a range of 0 to a°, the second angle θ is in a range of b° to c°, the third angle β is in a range of d° to 90°, and 0<a<b<c<d; and a∈[20,30], b∈[20,30], c∈[55, 65], and d∈[55, 65]. In an embodiment, a∈[23,30], b∈[23,30], c∈[58, 62], and d∈[58, 62].

In an embodiment, a length of an interval [θ,a] is not smaller than 23, a length of an interval [a,b] is not greater than 5, and a length of an interval [c,d] is not greater than 5. In an embodiment, a length of an interval [b,c] is not smaller than 23.

By way of example and not limitation, in an embodiment, a is 25°, b is 30°, c is 58°, and d is 60°.

In an embodiment, the wavelength λ of the predetermined light is in a range of 380 nm to 470 nm (such as 380 nm, 420 nm and 470 nm). In an embodiment, the wavelength λ is in a range of 424 nm to 464 nm (such as 424 nm, 444 nm and 464 nm).

In an embodiment, in each dielectric unit 221, a difference between the optical thickness of the first material layer 222 and the optical thickness of the second material layer 223 is at least 50 nm.

By way of example and not limitation, the wavelength λ is in a range of 434 nm to 454 nm, and the optical thickness of the first material layer 222 is in a range of 65 nm to 125 nm. The optical thickness of the second material layer 223 is in a range of 8 nm to 25 nm. In an embodiment, the optical thickness of the first material layer 222 is in a range of 70 nm to 120 nm, and the optical thickness of the second material layer 223 is in a range of 10 nm to 22 nm.

In an embodiment, the light-splitting layer 220 includes n layers of dielectric units 221, and n is not smaller than 10 and is not greater than 25. When n is too small, the reflective effects of the light-splitting layer 220 on the light with the incident complementary angle of the first angle α and the light with the incident complementary angle of the third angle β are not good, and when n is too large, the transmission effect of the light-splitting layer 220 on the light with the incident complementary angle of the second angle θ is not good.

In an embodiment, a sum of the optical thicknesses of all the first material layers 222 of the light-splitting layer 220 is not smaller than 1500 nm and is not greater than 1700 nm. A sum of the optical thicknesses of all the second material layers 223 of the light-splitting layer 220 is not smaller than 250 nm and is not greater than 300 nm.

Hereinafter, the light-emitting element 200 of the disclosure will be described through a control experiment.

### Experiment Group 1

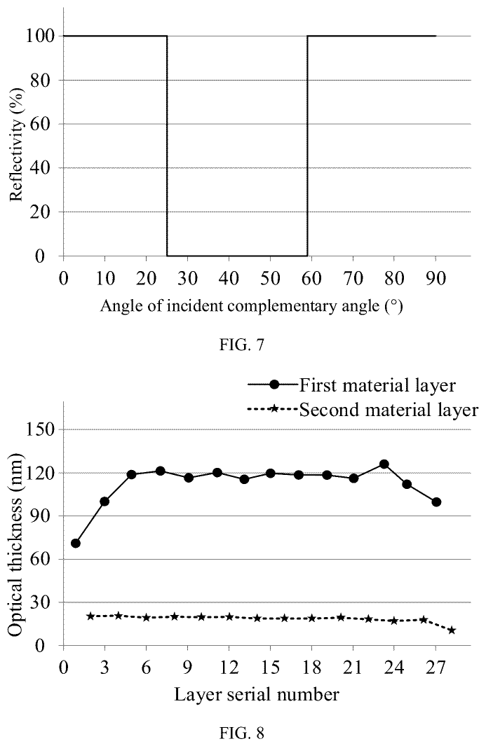

A first light-emitting element is provided based on the aforementioned light-emitting element 200, the first light-emitting element adopts the structure of the disclosure, and the same parts between the first light-emitting element and the aforementioned light-emitting element 200 are not repeated here. Further limitations of the first light-emitting element are that the first material layer 222 is a silica layer, the second material layer 223 is a titanium oxide layer, and a total number of layers of all the first material layers 222 and all the second material layers 223 of the light-splitting layer 220 is 28. When each first material layer 222 is counted as one material layer, and each second material layer 223 is counted as one material layer, according to a direction from the backlight surface 202 to the light-emitting surface 201, multiple material layers formed by repeatedly stacking the first material layers 222 and the second material layers 223 within the light-splitting layer 220 are numbered, a layer serial numbers of each material layer are sequentially 1 to 28, and the optical thicknesses of the multiple material layers are shown in FIG. 8.

### Control Group 1

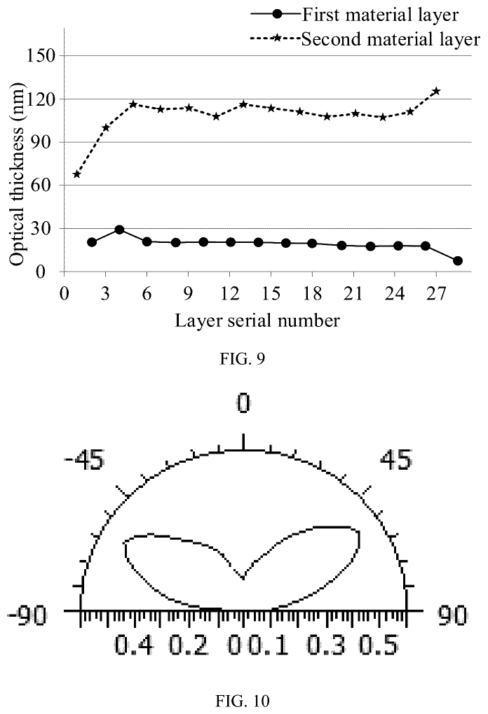

A second first light-emitting element is provided based on the aforementioned light-emitting element 200, and the same parts between the second light-emitting element and the first light-emitting element are not repeated here. Differences between the first light-emitting element and the second light-emitting element are that the first material layer 222 is a titanium oxide layer, the second material layer 223 is a silica layer, and a total number of layers of all the first material layers 222 and all the second material layers 223 of the light-splitting layer 220 is 28. When each first material layer 222 is counted as one material layer, and each second material layer 223 is counted as one material layer, according to the direction from the backlight surface 202 to the light-emitting surface 201, multiple material layers formed by repeatedly stacking the first material layers 222 and the second material layers 223 within the light-splitting layer 220 are numbered, a layer serial numbers of each material layer are sequentially 1 to 28, and the optical thicknesses of the multiple material layers are shown in FIG. 9.

### Experiment Comparison

The performances of the first light-emitting element and the second light-emitting element are compared in four aspects, and the four aspects are respectively a first comparison, a second comparison, a third comparison and a fourth comparison.

In the first comparison, the reflectivity of the light-splitting layer of the first light-emitting element and the reflectivity of the light-splitting layer of the second light-emitting element are detected to obtain the relationship between their respective reflectivity and incident complementary angle, thereby obtaining FIG. 6.

As shown in FIG. 6, the interval [θ,a] corresponding to the light-splitting layer of the first light-emitting element tends to [0,25], the interval [a,b] corresponding to the light-splitting layer of the first light-emitting element tends to [25,33], and its length tends to 8. The interval [0,a] corresponding to the light-splitting layer of the second light-emitting element tends to [0,20], the interval [a,b] corresponding to the light-splitting layer of the second light-emitting element tends to [20,33], and its length tends to 13. Compared to the interval [a,b] corresponding to the light-splitting layer of the second light-emitting element, the length of the interval [0,a] corresponding to the light-splitting layer of the first light-emitting element increases by nearly 5 units, thereby improving the efficiency of light extraction.

Under ideal conditions, as shown in FIG. 7, for the light-splitting layer of the first light-emitting element, the corresponding interval [a,b] tends to [0,25], the length of the corresponding interval [a,b] tends to 0, a length of the corresponding interval [c,d] tends to 0, and a length of the corresponding interval [b,c] tends to 35.

In the second comparison, the first light-emitting element and the second light-emitting element are detected, thereby obtaining Table 1.

TABLE 1
Comparison of detection parameters

| | | VF1 | WLD | LOP | | | | | |
|---|---|---|---|---|---|---|---|---|---|
| Product | | Full- | Full- | Full- | | VF1 | WLP | LOP | |
| batch | Product | measured | measured | measured | | Packaged | Packaged | Packaged | |
| number | category | brightness | brightness | brightness | ▴LOP | brightness | brightness | brightness | ▴LOP |
| 02 | First | 5.558 | 442.9 | 20.12 | 2.20% | 5.558 | 447.7 | 14.34 | 0.17% |
| | light- | | | | | | | | |
| | emitting | | | | | | | | |
| | element | | | | | | | | |
| 02 | Second | 5.557 | 443.0 | 19.68 | / | 5.557 | 447.9 | 14.32 | / |
| | light- | | | | | | | | |
| | emitting | | | | | | | | |
| | element | | | | | | | | |
| 03 | First | 5.559 | 443.6 | 20.05 | 2.59% | 5.559 | 449.0 | 14.47 | 1.37% |
| | light- | | | | | | | | |
| | emitting | | | | | | | | |
| | element | | | | | | | | |
| 03 | Second | 5.558 | 443.5 | 19.55 | / | 5.558 | 448.7 | 14.67 | / |
| | light- | | | | | | | | |
| | emitting | | | | | | | | |
| | element | | | | | | | | |
| 04 | First | 5.559 | 443.1 | 20.14 | 2.48% | 5.559 | 44841% | 14.57 | 0.91% |
| | light- | | | | | | | | |
| | emitting | | | | | | | | |
| | element | | | | | | | | |
| 04 | Second | 5.559 | 443.0 | 19.65 | / | 5.559 | 448.4 | 14.70 | / |
| | light- | | | | | | | | |
| | emitting | | | | | | | | |
| | element | | | | | | | | |
| 09 | First | 5.553 | 443.8 | 19.81 | 2.25% | 5.553 | 449.1 | 14.51 | 1.54% |
| | light- | | | | | | | | |
| | emitting | | | | | | | | |
| | element | | | | | | | | |
| 09 | Second | 5.552 | 443.9 | 19.38 | / | 5.552 | 449.0 | 14.29 | / |
| | light- | | | | | | | | |
| | emitting | | | | | | | | |
| | element | | | | | | | | |
| 10 | First | 5.559 | 442.9 | 19.69 | 1.89% | 5.559 | 448.0 | 14.40 | 1.23% |
| | light- | | | | | | | | |
| | emitting | | | | | | | | |
| | element | | | | | | | | |
| 10 | Second | 5.557 | 443.2 | 19.32 | / | 5.557 | 447.8 | 14.23 | / |
| | light- | | | | | | | | |
| | emitting | | | | | | | | |
| | element | | | | | | | | |
| 13 | First | 5.558 | 443.1 | 19.93 | 0.35% | 5.559 | 448.6 | 14.53 | −0.98% |
| | light- | | | | | | | | |
| | emitting | | | | | | | | |
| | element | | | | | | | | |
| 13 | Second | 5.559 | 443.3 | 19.86 | / | 5.558 | 448.3 | 14.39 | / |
| | light- | | | | | | | | |
| | emitting | | | | | | | | |
| | element | | | | | | | | |
| 14 | First | 5.567 | 442.6 | 19.75 | 3.15% | 5.565 | 448.0 | 14.66 | 2.49% |
| | light- | | | | | | | | |
| | emitting | | | | | | | | |
| | element | | | | | | | | |
| 14 | Second | 5.565 | 442.9 | 19.14 | / | 5.567 | 448.2 | 14.31 | / |
| | light- | | | | | | | | |
| | emitting | | | | | | | | |
| | element | | | | | | | | |
| 20 | First | 5.566 | 442.9 | 19.92 | 3.68% | 5.562 | 448.8 | 14.42 | 1.70% |
| | light- | | | | | | | | |
| | emitting | | | | | | | | |
| | element | | | | | | | | |
| 20 | Second | 5.562 | 443.3 | 19.21 | / | 5.566 | 448.1 | 14.18 | / |
| | light- | | | | | | | | |
| | emitting | | | | | | | | |
| | element | | | | | | | | |
| 23 | First | 5.572 | 442.5 | 19.79 | 1.96% | 5.571 | 448.0 | 14.50 | 0.86% |
| | light- | | | | | | | | |
| | emitting | | | | | | | | |
| | element | | | | | | | | |
| 23 | Second | 5.571 | 442.5 | 19.41 | / | 5.572 | 448.2 | 14.37 | / |
| | light- | | | | | | | | |
| | emitting | | | | | | | | |
| | element | | | | | | | | |
| 24 | First | 5.574 | 442.2 | 19.75 | 1.76% | 5.570 | 448.0 | 14.61 | 1.57% |
| | light- | | | | | | | | |
| | emitting | | | | | | | | |
| | element | | | | | | | | |
| 24 | Second | 5.570 | 442.5 | 19.40 | / | 5.574 | 447.7 | 14.39 | / |
| | light- | | | | | | | | |
| | emitting | | | | | | | | |
| | element | | | | | | | | |
| Mean | First | 5.562 | 443.0 | 19.89 | 2.23% | 5.561 | 448.4 | 14.50 | 1.31% |
| value | light- | | | | | | | | |
| | emitting | | | | | | | | |
| | element | | | | | | | | |
| | Second | 5.561 | 443.1 | 19.46 | / | 5.562 | 448.2 | 14.38 | / |
| | light- | | | | | | | | |
| | emitting | | | | | | | | |
| | element | | | | | | | | |

As shown above, in Table 1, VF1 represents a voltage, and unit is volt (V); WLD represents a wavelength, and unit is nm; LOP represents brightness, and unit is milliwatt (mW). Products in Table 1 are the light-emitting elements, and the products with the same product batch number are products produced in the same batch.

As shown in Table 1, the full-measured brightness refers to the brightness before packaging, and the packaged brightness refers to the brightness after packaging. The full-measured brightness of the first light-emitting element is increased by an average of 2.23% compared to the second light-emitting element. The packaged brightness of the first light-emitting element is increased by an average of 1.31% compared to the second light-emitting element.

In the third comparison, molding the first light-emitting element and the second light-emitting element, and the molding refers to packaging, thereby obtaining Table 2.

TABLE 2
Comparison of molding results

| Product batch | Product | Voltage-current | Peak | Radiometric | |
|---|---|---|---|---|---|
| number | category | source/V | wavelength/nm | measurement/mW | Δlop |
| 04 | Second light- | 5.555 | 442.570 | 18.680 | / |
| | emitting element | | | | |
| | First light- | 5.574 | 442.630 | 18.838 | 0.844% |
| | emitting element | | | | |
| 03 | Second light- | 5.556 | 442.850 | 18.752 | / |
| | emitting element | | | | |
| | First light- | 5.560 | 442.824 | 18.906 | 0.824% |
| | emitting element | | | | |
| 13 | Second light- | 5.559 | 442.519 | 18.597 | / |
| | emitting element | | | | |
| | First light- | 5.548 | 443.187 | 18.759 | 0.866% |
| | emitting element | | | | |
| 24 | Second light- | 5.583 | 442.103 | 18.460 | / |
| | emitting element | | | | |
| | First light- | 5.568 | 442.540 | 18.823 | 1.971% |
| | emitting element | | | | |
| 10 | Second light- | 5.558 | 442.272 | 18.693 | / |
| | emitting element | | | | |
| | First light- | 5.553 | 442.391 | 18.818 | 0.667% |
| | emitting element | | | | |
| 09 | Second light- | 5.548 | 443.179 | 18.582 | / |
| | emitting element | | | | |
| | First light- | 5.544 | 443.664 | 18.834 | 1.356% |
| | emitting element | | | | |
| 20 | Second light- | 5.569 | 442.691 | 18.528 | / |
| | emitting element | | | | |
| | First light- | 5.566 | 442.920 | 18.893 | 1.968% |
| | emitting element | | | | |
| 14 | Second light- | 5.568 | 442.477 | 18.388 | / |
| | emitting element | | | | |
| | First light- | 5.562 | 442.585 | 18.829 | 2.402% |
| | emitting element | | | | |
| 23 | Second light- | 5.573 | 442.266 | 18.436 | / |
| | emitting element | | | | |
| | First light- | 5.560 | 442.483 | 18.856 | 2.278% |
| | emitting element | | | | |
| Mean value | Second light- | 5.563 | 442.547 | 18.569 | / |
| | emitting element | | | | |
| | First light- | 5.559 | 442.803 | 18.840 | 1.460% |
| | emitting element | | | | |

As above, in Table 2, voltage-current source refers to the voltage provided by the current source as a power source. The products in Table 2 are the light-emitting elements, the products with the same product batch number are products produced in the same batch, and the products with different product batch numbers are products produced in different batches.

As shown in Table 2, in the molding results, the brightness of the first light-emitting element is increased by 1.46% on average compared to the second light-emitting element.

In the fourth comparison, light pattern comparison is performed to obtain Table 3.

TABLE 3
Comparison of light pattern

| | Product | Symmetry | | | |
|---|---|---|---|---|---|
| Product | serial | Left extremum/ | Right extremum/ | Left extremum/ | Light |
| category | number | 0 value | 0 value | right extremum | pattern |
| First light- | 1 | 4.50 | 4.45 | 1.01 | First light |
| emitting | | | | | pattern |
| element | | | | | |
| Second light- | 2 | 2.59 | 2.33 | 1.11 | Second light |
| emitting | | | | | pattern |
| element | | | | | |
| First light- | 3 | 4.61 | 4.56 | 1.01 | Third light |
| emitting | | | | | pattern |
| element | | | | | |
| Second light- | 4 | 3.76 | 3.54 | 1.06 | Fourth light |
| emitting | | | | | pattern |
| element | | | | | |

As mentioned above, the products in Table 3 are the light-emitting elements, and different product serial numbers represent different light-emitting elements.

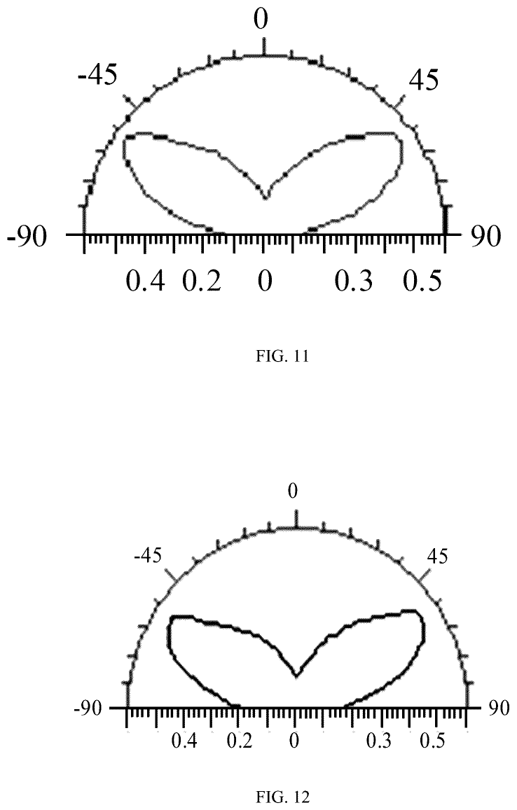

Referring to Table 3 in conjunction with FIGS. 10-11, a ratio of the left extremum to the right extremum of the first light-emitting element with the product serial number 1 is 1.01, and a ratio of the left extremum to the right extremum of the second light-emitting element with the product serial number 2 is 1.11. The closer the ratio of the left extremum to the right extremum is to 1, the more symmetrical the left and right emission of the light-emitting element. Apparently, the ratio of the left extremum to the right extremum of the first light-emitting element with the product serial number 1 is lower than the ratio of the left extremum to the right extremum of the second light-emitting element with the product serial number 2. That is, the symmetry of the first light pattern of the first light-emitting element with the product serial number 1 is better than the symmetry of the second light pattern of the second light-emitting element with the product serial number 2.

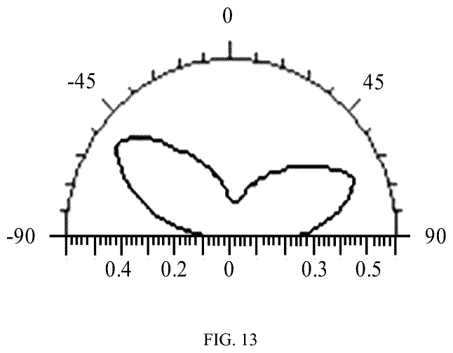

Referring to Table 3 in conjunction with FIG. 12 to FIG. 13, a ratio of the left extremum to the right extremum of the first light-emitting element with the product serial number 3 is 1.01, and a ratio of the left extremum to the right extremum of the second light-emitting element with the product serial number 4 is 1.06. Apparently, the ratio of the left extremum to the right extremum of the first light-emitting element with the product serial number 3 is lower than the ratio of the left extremum to the right extremum of the second light-emitting element with the product serial number 4. That is, the symmetry of the third light pattern of the first light-emitting element with the product serial number 3 is better than the symmetry of the fourth light pattern of the second light-emitting element with the product serial number 4.

In addition, the disclosure further provides a light-emitting device, and the light-emitting device includes an encapsulation bracket and the light-emitting element. The light-emitting element is fixed on the encapsulation bracket, which is the aforementioned light-emitting element 200, and is not repeated here.

In addition, the disclosure further provides a display device, the display device includes multiple light-emitting elements, and each of the multiple light-emitting elements is the aforementioned light-emitting element 200, and is not repeated here.

The above are merely embodiments of the disclosure, and are not intended to limit the patent scope of the disclosure. Any equivalent structure or equivalent process transformation made using the contents of the disclosure specification and drawings, or directly or indirectly applied in other related technical fields, are also included in the patent protection scope of the disclosure.

What is claimed is:

1. A light-emitting element, wherein the light-emitting element is a flip-chip light-emitting diode, and has a light-emitting surface and a backlight surface respectively located on outermost sides of the flip-chip light-emitting diode and opposite to each other; the flip-chip light-emitting diode comprises an epitaxial staked layer and a light-splitting layer, and the epitaxial stacked layer is configured to generate predetermined light; and the light-splitting layer is disposed on a side of the epitaxial stacked layer proximate to the light-emitting surface; and
wherein the light-splitting layer is configured to reflect predetermined light with an incident complementary angle of a first angle, transmit predetermined light with an incident complementary angle of a second angle, and reflect predetermined light with an incident complementary angle of a third angle; and the first angle is smaller than the second angle, and the second angle is smaller than the third angle.

2. The light-emitting element as claimed in claim 1, wherein the light-splitting layer comprises multiple layers of dielectric units, and the multiple layers of dielectric units cooperate with each other to achieve functions of the light-splitting layer; and
wherein each of the multiple layers of dielectric units comprises a first material layer and a second material layer; in each of the multiple layers of dielectric units, the first material layer is located on a side of the second material layer proximate to the epitaxial stacked layer, an optical thickness of the first material layer is greater than that of the second material layer, and a refractive index of the first material layer is lower than that of the second material layer.

3. The light-emitting element as claimed in claim 1, wherein the first angle is in a range of 0 to a°, the second angle is in a range of b° to c°, the third angle is in a range of d° to 90°, and 0<a<b<c<d; and a∈[20,30], b∈[20,30], c∈[55, 65], and d∈[55, 65].

4. The light-emitting element as claimed in claim 3, wherein a length of an interval [a,b] is not greater than 5, and a length of an interval [c,d] is not greater than 5.

5. The light-emitting element as claimed in claim 3, wherein a length of an interval [b,c] is not smaller than 23.

6. The light-emitting element as claimed in claim 2, wherein in each of the multiple layers of dielectric units, a difference between the optical thickness of the first material layer and the optical thickness of the second material layer is at least 50 nm.

7. The light-emitting element as claimed in claim 2, wherein the optical thickness of the first material layer is in a range of 65 nm to 125 nm.

8. The light-emitting element as claimed in claim 2, wherein the optical thickness of the second material layer is in a range of 8 nm to 25 nm.

9. The light-emitting element as claimed in claim 2, wherein the light-splitting layer comprises n layers of the dielectric units, and n is not smaller than 10 and is not greater than 25.

10. The light-emitting element as claimed in claim 2, wherein a sum of the optical thicknesses of all the first material layers of the light-splitting layer is not smaller than 1500 nm and is not greater than 1700 nm.

11. The light-emitting element as claimed in claim 2, wherein a sum of the optical thicknesses of all the second material layers of the light-splitting layer is not smaller than 250 nm and is not greater than 300 nm.

12. The light-emitting element as claimed in claim 1, wherein a reflectivity of the light-splitting layer on predetermined light with the incident complementary angle of the first angle and a wavelength of 420 nm to 470 nm is at least 95%.

13. The light-emitting element as claimed in claim 1, wherein a transmissivity of the light-splitting layer on predetermined light with the incident complementary angle of the second angle and a wavelength of 380 nm to 440 nm is at least 90%.

14. The light-emitting element as claimed in claim 1, wherein a reflectivity of the light-splitting layer on predetermined light with the incident complementary angle of the third angle and a wavelength of 380 nm to 410 nm is at least 98%.

15. A light-emitting element, having a light-emitting surface and a backlight surface respectively located on outermost sides of the light-emitting element and opposite to each other; wherein the light-emitting element comprises a light-emitting functional layer, a light-splitting layer and an insulating reflective layer, and the light-emitting functional layer is configured to generate predetermined light; and the light-splitting layer is disposed on a side of the light-emitting functional layer proximate to the light-emitting surface, and the insulating reflective layer is disposed on a side of the light-emitting functional layer proximate to the backlight surface; and
wherein the insulating reflective layer is configured to reflect incident predetermined light; the light-splitting layer is configured to reflect predetermined light with an incident complementary angle of a first angle, transmit predetermined light with an incident complementary angle of a second angle, and reflect predetermined light with an incident complementary angle of a third angle; and the first angle is smaller than the second angle, and the second angle is smaller than the third angle.

16. The light-emitting element as claimed in claim 15, wherein the light-emitting functional layer comprises a first semiconductor layer, a light-emitting layer and a second semiconductor layer stacked in that order, the second semiconductor layer is located on a side of the insulating reflective layer facing away from the backlight surface, the first semiconductor layer is a n-type nitride semiconductor layer, the light-emitting layer comprises a multiple quantum well (MQW) structure, and the second semiconductor layer is a p-type nitride semiconductor layer.

17. The light-emitting element as claimed in claim 15, wherein the light-splitting layer comprises multiple layers of dielectric units, and the multiple layers of dielectric units cooperate with each other to achieve functions of the light-splitting layer;
wherein each of the multiple layers of dielectric units comprises a first material layer and a second material layer; in each of the multiple layers of dielectric units, the first material layer is located on a side of the second material layer proximate to the light-emitting functional layer, an optical thickness of the first material layer is greater than that of the second material layer, and a refractive index of the first material layer is lower than that of the second material layer; and
wherein the first angle is in a range of 0° to a°, the second angle is in a range of b° to c°, the third angle is in a range of d° to 90°, and 0<a<b<c<d; and a∈[20,30], b∈[20,30], c∈[55, 65], and d∈[55, 65].

18. The light-emitting element as claimed in claim 17, wherein in each of the multiple layers of dielectric units, a difference between the optical thickness of the first material layer and the optical thickness of the second material layer is at least 50 nm, the optical thickness of the first material layer is in a range of 65 nm to 125 nm, the optical thickness of the second material layer is in a range of 8 nm to 25 nm, the first material layer is a silica layer, and the second material layer is a titanium oxide layer.

19. A light-emitting device, comprising an encapsulation bracket and the light-emitting element, wherein the light-emitting element is fixed on the encapsulation bracket, and is the light-emitting element as claimed in claim 1.

20. A display device, comprising multiple light-emitting elements, wherein each of the multiple light-emitting elements is the light-emitting element as claimed in claim 15.
